(19) United States
(12) Patent Application Publication
(10) Pub. No.: US 2007/0178658 A1
(43) Pub. Date: Aug. 2, 2007

(54) Patterning and aligning semiconducting nanoparticles

(76) Inventors: Tommie W. Kelley, Shorevlew, MN (US); Timothy D. Dunbar, Woodbury, MN (US)

Correspondence Address: 3M INNOVATIVE PROPERTIES COMPANY, PO BOX 33427, ST. PAUL, MN, 55133-3427, US

(21) Appl. No.: 11/156,800

(22) Filed: Jun. 20, 2005

Related U.S. Application Data
(60) Provisional application No. 60/581,414, filed on Jun. 21, 2004.

(51) Int. Cl. H01L 21/76

(52) U.S. Cl. 438/401

(57) ABSTRACT

A method is provided for making a device comprising aligned semiconducting nanoparticles and a receptor substrate comprising the steps of: a) aligning a plurality of first semiconducting nanoparticles; b) depositing the aligned first semiconducting nanoparticles on a first donor sheet; and c) transferring at least a portion of the aligned first semiconducting nanoparticles to a receptor substrate by the application of laser radiation. Typically, the semiconducting nanoparticles are inorganic semiconducting nanoparticles. The alignment step may be accomplished by any suitable method, typically including: 1) alignment by capillary flow in or on a textured or microchanneled surface; 2) alignment by templating on a self-assembled monolayer (SAM); 3) alignment by templating on a textured polymer surface; or 4) alignment by mixing in a composition that includes nematic liquid crystals followed by shear orientation of the nematic liquid crystals. In some embodiments, the method additionally comprises the steps of: d) aligning a second plurality of second nanoparticles; e) depositing the aligned second nanoparticles on the same donor sheet or a second donor sheet; and f) transferring at least a portion of the aligned second nanoparticles to the same receptor substrate by the application of laser radiation. The second nanoparticles may be conducting particles, non-conducting particles, or semiconducting nanoparticles, including inorganic semiconducting nanoparticles, and may be the same or different in composition from the first semiconducting nanoparticles. In addition, devices made according to the methods of the present invention are provided.

### CROSS REFERENCE TO RELATED APPLICATION

This application claims priority to U.S. Provisional Patent Application No. 60/581,414, filed Jun. 21, 2004.

### FIELD OF THE INVENTION

This invention relates to methods of patterning and/or aligning semiconducting nanoparticles and articles comprising patterned and/or aligned semiconducting nanoparticles. This invention may be useful in the fabrication of thin film electronic devices such as transistors, diodes, and the like.

### SUMMARY OF THE INVENTION

Briefly, the present invention provides a method of making a device comprising aligned semiconducting nanoparticles and a receptor substrate, where the method comprises the steps of: a) aligning a plurality of first semiconducting nanoparticles; b) depositing the aligned first semiconducting nanoparticles on a first donor sheet; and c) transferring at least a portion of the aligned first semiconducting nanoparticles to a receptor substrate by the application of laser radiation. Typically, the semiconducting nanoparticles are inorganic semiconducting nanoparticles. The alignment step may be accomplished by any suitable method, typically including: 1) alignment by capillary flow in or on a textured or microchanneled surface; 2) alignment by templating on a self-assembled monolayer (SAM); 3) alignment by templating on a textured polymer surface; or 4) alignment by mixing in a composition that includes nematic liquid crystals followed by shear orientation of the nematic liquid crystals. In some embodiments, the method additionally comprises the steps of: d) aligning a second plurality of second nanoparticles; e) depositing the aligned second nanoparticles on the same donor sheet or a second donor sheet; and f) transferring at least a portion of the aligned second nanoparticles to the same receptor substrate by the application of laser radiation. The second nanoparticles may be conducting particles, non-conducting particles, or semiconducting nanoparticles, including inorganic semiconducting nanoparticles, and may be the same or different in composition from the first semiconducting nanoparticles. In addition, devices made according to the methods of the present invention are provided.

### DETAILED DESCRIPTION

Any suitable semiconducting nanoparticles can be used in the practice of the present invention. The nanoparticles are typically less than 500 nm in thickness, i.e., in smallest dimension, more typically less than 200 nm, and more typically less than 100 nm, and in some embodiments may be less than 50 nm or less than 20 nm in thickness. Typical nanoparticles useful in the practice of the present invention may include nanowires, nanorods, nanotubes, nanoribbons and nanocrystals. The nanoparticles may be branched to form tripods or tetrapods.

Typical semiconducting nanoparticles are composed of II-VI materials, III-V materials, Group IV materials, or combinations thereof. Suitable II-VI materials may be composed of alloys of any number of Group II materials, most typically those selected from the group consisting of Zn, Cd, Be and Mg, with any number of Group VI materials, most typically those selected from the group consisting of Se, Te, and S. Suitable II-VI materials may include zinc oxides or magnesium oxides. Suitable III-V materials may be composed of alloys of any number of Group III materials, most typically those selected from the group consisting of In, Al and Ga, with any number of Group V materials, most typically those selected from the group consisting of As, P and Sb. Suitable Group IV materials may include Si and Ge. Alternately, organic semiconductor materials can be used, which may include perylene, pentacene, tetracene, metallophthalocyanines, copper phthalocyanine, sexithiophene, or derivatives thereof. In addition, layered, segmented, alloyed or otherwise compounded combinations of any of the above materials with each other or with electrically conducting materials may be used.

The semiconducting nanoparticles useful in the practice of the present invention may be made by any suitable method, which may include methods taught in Int. Pub. No. WO 2004/027822 A2, U.S. Pat. App. Pub. No. 2004/0005723 A1, and references cited therein, incorporated herein by reference. Additional methods which may be useful in the manufacture of semiconducting nanoparticles may include arc discharge, plasma enhanced chemical vapor deposition (PECVD), physical vapor deposition, and the like.

In some embodiments of the present invention, the semiconducting nanoparticles are aligned by capillary flow in or on a textured or microchanneled (which may include nanochanneled) surface. A composition including the semiconducting nanoparticles is applied to capillaries fabricated in or on the surface, such that capillary action will draw the composition into the capillaries, forcing the nanoparticles to orient along the length of the capillary. In addition, nanoparticles may tend to align during drying of liquid compositions, providing a second process that serves to align the nanoparticles. Any suitable composition including the semiconducting nanoparticles may be used. The composition is most typically a fluid or a suspension. In addition to the semiconducting nanoparticles, the composition may include solvents, vehicles, polymers, or other materials, as well as additives such as fillers, dispersants, dyes, preservatives, and the like. Any suitable textured or microchanneled surface article may be used, including glass, ceramic, metal, or polymeric surfaces. The textures or capillary patterns may be 2- or 3-dimensional, and may encompass one or more than one face of the textured or microchanneled surface device. The textures or capillary patterns may comprise open channels or canals, closed tubes or veins, isolated wells or combinations of each. In the case of isolated wells, the drying process may predominate over the capillary process. In one embodiment, the textured or microchanneled surface article comprises channels having a single orientation. In an alternate embodiment, the textured or microchanneled surface article comprises various regions having differing orientations. In a further embodiment, the textured or microchanneled surface article comprises various regions having channels with differing degrees of orientation vs. randomness. In a further embodiment, the textured or microchanneled surface article comprises various regions having differing concentration of capillary channels, so as to modulate the amount of oriented material present in that region. In a further embodiment, the textured or microchanneled surface article may comprise regions having crossed arrays capillary channels, such that the regions of aligned nanotubes cross at 90 degree or other orientation on the surface. Articles comprising microfluidic channels which may be useful in the practice of the present invention may be made according to the methods described in U.S. Pat. No. 6,375,871, U.S. Pat. App. Pub. Nos. 2002/0098124 and 2004/0042937, and references cited therein, incorporated herein by reference. Additional methods which may be useful in the manufacture of articles comprising microfluidic channels may include photolithography, dry etching, diamond turning, laser ablation, casting, embossing, and the like.

In some embodiments of the present invention, the semiconducting nanoparticles are aligned by templating on a self-assembled monolayer (SAM). A composition including the semiconducting nanoparticles is applied to a surface treated with a self-assembled monolayer (SAM) on its surface, such that the nanoparticles will tend to orient with the SAM. Any suitable composition including the semiconducting nanoparticles may be used, as noted above. The self-assembled monolayer (SAM) made be made by any suitable method, including those described in U.S. Pat. No. 6,518,168 and references cited therein, incorporated herein by reference.

In some embodiments of the present invention, the semiconducting nanoparticles are aligned by templating on a textured polymer surface, such as a rubbed polyimide surface, such as is used in alignment of liquid crystals, or a stretched polymer film. A composition including the semiconducting nanoparticles is applied to a textured polymer surface. Any suitable composition including the semiconducting nanoparticles may be used, as noted above.

In some embodiments of the present invention, the semiconducting nanoparticles are aligned by a process that includes, first, mixing the semiconducting nanoparticles in a composition that includes nematic liquid crystals, and, second, shear orienting said nematic liquid crystals. Any suitable nematic liquid crystals and any suitable method of shear orientation may be used, including those described in Dierking, “Aligning and Reorienting Carbon Nanotubes with Nematic Liquid Crystals, Adv. Mater. 2004, 16, No. 11, June 4, pp. 865-869, and references cited therein, incorporated herein by reference.

In any of the above methods of aligning semiconducting nanoparticles, the composition including the semiconducting nanoparticles may be applied by printing or coating methods, including ink jet printing, knife blade coating, doctor blade coating, spin coating, and the like. The composition including the semiconducting nanoparticles may additionally be patterned during this application step, in particular where printing methods of application are used, such as ink jet printing, Laser Induced Thermal Imaging (LITI), and the like. In addition, printing methods of application, such as ink jet printing, LITI, and the like, may be used for patterning of non-oriented semiconducting nanoparticles.

In some embodiments of the alignment methods described above, the article comprising the alignment mechanism is the substrate of an electronic device. In these embodiments, the alignment mechanism serves to orient the semiconducting nanoparticles after application to the substrate by any of the application methods described above. The electronic device substrate may additionally comprise electronic contacts, conductors, insulators, heat management mechanisms, and the like.

In some embodiments of the alignment methods described above, the article comprising the alignment mechanism is a coating die.

In some embodiments of the present invention, the semiconducting nanoparticles are patterned by Laser Induced Thermal Imaging (LITI). In this method, a composition including the semiconducting nanoparticles is borne on a donor sheet, as described in U.S. Pat. Nos. 6,114,088, 6,194,119, 6,358,664, 6,485,884, 6,521,324, incorporated herein by reference. The donor sheet is brought into contact with a receptor substrate and the composition including the semiconducting nanoparticles is selectively transferred to the receptor substrate by application of laser radiation. This method allows for arbitrary patterning of the composition including the semiconducting nanoparticles, including the formation of “islands.” In this embodiment, any suitable composition including the semiconducting nanoparticles may be used. The composition may be a solid, a fluid, a suspension, a gel or any suitable form of matter. In addition to the semiconducting nanoparticles, the composition may include solvents, vehicles, polymers, matrices or other materials, as well as additives such as fillers, dispersants, dyes, preservatives, and the like. Liquid compositions may be dried or solidified before transfer. In one embodiment, the composition comprises components that can be removed by evaporation, decomposition or both, which may include solvents, vehicles, polymers, matrices or other materials. Decomposition may involve application of heat, chemicals, radiation, time, or some other agent, or some combination thereof. Alternately, the composition may comprise only the semiconducting nanoparticles neat.

In some embodiments of the present invention wherein the semiconducting nanoparticles are patterned by Laser Induced Thermal Imaging (LITI), an article comprising one or more thin film electronic devices is made. In one embodiment, an electronic circuit comprising many thin film electronic devices is made, which may be simple in design or may be comparable in complexity to an integrated circuit chip. In some embodiments of the present invention, an article comprising thin film electronic devices may be made by a method including a single LITI step. In some embodiments of the present invention, an article comprising thin film electronic devices may be made by a method including a two or more LITI steps. The multiple LITI steps may employ donor sheets that differ in the composition, shape, size, direction or degree of orientation, or concentration of semiconducting nanoparticles. In some embodiments of the present invention, an article comprising thin film electronic devices may be made by one or more multilayer LITI steps. Additional layers in such a multilayer LITI may include metals, insulators, dielectrics, and the like, which may be patterned by methods such as shadow masking, lithography, and the like.

In some embodiments of the present invention wherein the semiconducting nanoparticles are patterned by Laser Induced Thermal Imaging (LITI), the composition including the semiconducting nanoparticles is aligned prior to patterning by one or more of the alignment methods discussed above. In one embodiment, the nanoparticles are aligned on an article comprising a textured or microchanneled surface and transferred from there to a donor sheet. In one embodiment, the textured or microchanneled surface comprises channels having a single orientation. In an alternate embodiment, the textured or microchanneled surface comprises various regions having differing orientations.

In a further embodiment of the present invention wherein the semiconducting nanoparticles are patterned Laser Induced Thermal Imaging (LITI), the composition including the semiconducting nanoparticles is aligned on the donor sheet prior to patterning. In this embodiment, the donor sheet may comprise a textured or microchanneled surface. In one embodiment, the donor sheet comprises channels having a single orientation. In an alternate embodiment, the donor sheet comprises various regions having channels with differing orientations. In a further embodiment, the donor sheet comprises various regions having differing degrees of orientation vs. randomness, so as to modulate the mobility, on/off ratio, or other devices parameters in specific regions of the substrate. In a further embodiment, the donor sheet comprises various regions having differing concentration of capillary channels, so as to modulate the amount of oriented material present in that region. In a further embodiment, the donor sheet may comprise regions having crossed arrays capillary channels, such that the regions of aligned nanotubes cross at 90 degree or other orientation on the donor sheet. The crossed, aligned nanotubes can be transferred, leaving a crossed array of semiconductor on the substrate.

Thus, in some embodiments, the present invention allows a circuit designer to deposit semiconducting nanoparticles on a substrate in a pattern of arbitrary design, in arbitrary orientations, including mixed orientations, in varying line densities and in varying degrees of orientation.

In some embodiments, the methods of aligning and/or patterning semiconducting nanoparticles during manufacture of an electronic device are also used to align and/or pattern conducting particles in the manufacture of the electronic device. In some embodiments, the methods of aligning and/or patterning semiconducting nanoparticles during manufacture of an electronic device are also used to align and/or pattern non-conducting or insulating particles in the manufacture of the electronic device.

This invention is useful in the manufacture of electronic devices.

Objects and advantages of this invention are further illustrated by the following examples, but the particular materials and amounts thereof recited in these examples, as well as other conditions and details, should not be construed to unduly limit this invention.

### EXAMPLES

Unless otherwise noted, all reagents were obtained or are available from Aldrich Chemical Co., Milwaukee, Wis., or may be synthesized by known methods.

### Preparatory Example 1—Preparation of Compound A, 1-[4,6-di(4-carboxyanilino)-1,3,5-triazin-2-yl]pyridinium hydrogen sulfate (A Nematic Triazine Derivative)

1-[4,6-di(4-carboxyanilino)-1,3,5-triazin-2-yl]pyridinium hydrogen sulfate was prepared as described in U.S. Pat. No. 5,948,487 (Sahouani et al) in Example 1 for the preparation of compound A, a nematic triazine derivative, as follows:

To a 500 ml three neck round-bottom flask with a thermometer, mechanical stirrer and condenser was added 117 ml of anhydrous pyridine. The mixture was heated to 70° C. and 39 g of 4,4′-[(6-chloro-1,3,5-triazine-2,4-diyl)diimino]bis-benzoic acid was added to give a heterogeneous mixture. The temperature was slowly increased to 85° C. and heated for one hour while the suspension was stirred vigorously. The mixture was cooled to 15° C. and the solid was collected by suction filtration, washed with pyridine, and air dried overnight at room temperature to give 47.69 g of a yellow solid.

A 4.44 g sample of the solid was dissolved in 115 ml of water containing 1.62 ml of 30% aqueous ammonium hydroxide solution. The mixture was stirred for ten minutes and filtered to remove a small amount of solid. The filtrate was transferred to a 250 ml three neck round bottom flask with a mechanical stirrer and a pH meter.

A solution of 4% by weight sulfuric acid in water was added slowly dropwise until the pH reached about 3.5. The solid was collected by suction filtration, stirred in 100 ml of water, and collected by filtration. The solid was then heated to 56° C. in 200 ml of acetone, collected, and air dried.

The resulting compound was subjected to nmr analysis, which showed a structure consistent with 1-[4,6-di(4-carboxyanilino)-1,3,5-triazin-2-yl]pyridinium hydrogen sulfate, which will hereinafter be called nematic compound A.

### Preparatory Example 2—Preparation of a Substrate/Light-to-Heat Conversion/Interlayer (LTHCI) Film

A carbon black light-to-heat conversion layer was prepared as described in U.S. Pat. No. 6,114,088 (Wolk), for example, by coating the following LTHC Coating Solution, according to Table 1, onto a 0.1 mm PET substrate with a Yasui Seiki Lab Coater, Model CAG-150 (Yasui Seiki Co., Bloomington, Ind.) using a microgravure roll of 381 helical cells per lineal cm (150 helical cells per lineal inch).

TABLE 1
LTHC Coating Solution

| | Parts by |
|---|---|
| Component | Weight |
| Raven ™ 760 Ultra carbon black pigment (available | 3.39 |
| from Columbian Chemicals, Atlanta, GA) | |
| Butvar ™ B-98 (polyvinylbutyral resin, available from | 0.61 |
| Monsanto, St. Louis, MO) | |
| Joncryl ™ 67 (acrylic resin, available from S.C. Johnson | 1.81 |
| & Son, Racine, WI) | |
| Elvacite ™ 2669 (acrylic resin, available from ICI | 9.42 |
| Acrylics, Wilmington, DE) | |
| Disperbyk ™ 161 (dispersing aid, available from Byk | 0.3 |
| Chemie, Wallingford, CT) | |
| FC-430 ™ (fluorochemical surfactant, available from | 0.012 |
| 3M, St. Paul, MN) | |
| Ebecryl ™ 629 (epoxy novolac acrylate, available from | 14.13 |
| UCB Radcure, N. Augusta, SC) | |
| Irgacure ™ 369 (photocuring agent, available from Ciba | 0.95 |
| Specialty Chemicals, Tarrytown, NY) | |
| Irgacure ™ 184 (photocuring agent, available from Ciba | 0.14 |
| Specialty Chemicals, Tarrytown, NY) | |
| propylene glycol methyl ether acetate | 16.78 |
| 1-methoxy-2-propanol | 9.8 |
| methyl ethyl ketone | 42.66 |

The coating was in-line dried at 40° C. and UV-cured at 6.1 m/min using a Fusion Systems Model 1600 (400 W/in) UV curing system fitted with H-bulbs (Fusion UV Systems, Inc., Gaithersburg, Md.). The dried coating had a thickness of approximately 3 microns.

Onto the carbon black coating of the light-to-heat conversion layer was rotogravure coated an Interlayer Coating Solution, according to Table 2, using the Yasui Seiki Lab Coater, Model CAG-150 (Yasui Seiki Co., Bloomington, Ind.). This coating was in-line dried (40° C.) and UV-cured at 6.1 m/min using a Fusion Systems Model I600 (600 W/in) fitted with H-bulbs. The thickness of the resulting interlayer coating was approximately 1.7 microns.

TABLE 2
Interlayer Coating Solution

| | Parts by |
|---|---|
| Component | Weight |
| Butvar ™ B-98 | 0.98 |
| Joncryl ™ 67 | 2.95 |
| Sartomer ™ SR351 ™ (trimethylolpropane | 15.75 |
| triacrylate, available from Sartomer, Exton, PA) | |
| Irgacure ™ 369 | 1.38 |
| Irgacure ™ 184 | 0.2 |
| 1-methoxy-2-propanol | 31.5 |
| methyl ethyl ketone | 47.24 |

### Example 1

### Alignment of Zinc Oxide Nanowires

A solution was made by sequentially adding to 4 g of purified water the following: 0.13 g of 30% ammonium hydroxide in water, 0.12 g 10% alkyl glucosides (available from Fitz Chem Corp, Itasca, Ill. as APG 325) in water, and 0.5 g nematic compound A from Preparatory Example 1. The solution was stirred for 1 hour. Zinc oxide nanowires (Nanolab, Newton, Mass.), 20-70 nanometers diameter, 3-10 microns long, were added and the mixture was stirred via magnetic stir bar for at least 1 hour.

About 0.3 ml of the mixture was coated by placing the mixture on the polymer substrate, holding a 6 inch long gap, 0.5 mil wet film thickness film applicator (Bird Film Applicator available from BYK-Gardner, Columbia, Md.) stationary and pulling a 4 inch wide polymer film beneath it by hand at a rate of approximately 50 cm/sec. The Bird Film Applicator was shimmed at its edges so that a gap of 4 to 8 microns exists between the polymer film surface and the film applicator. The particular substrate polymer used was a silica-primed poly(ethyelene terephthalate), also known as PET.

After coating, the film layers were allowed to dry to form a nanowire-containing matrix layer on a polymer substrate layer. The film layers are imaged using transmission electron microscopy (TEM). For imaging using scanning electron microscopy (SEM), the matrix is removed using reactive ion etching (RIE). Small samples of the nanowire in matrix film are cut off and loaded into a Technics Micro RIE Series 80 reactive ion etch machine. The films are processed for five minutes in a 150 W oxygen plasma.

### Example 2

### Transfer of Aligned Zinc Oxide Nanowires

The zinc oxide nanowire-containing mixture described in Example 1 is coated onto the substrate/light-to-heat conversion/interlayer film (from Preparatory Example 2) using the Bird Film Applicator in the manner described in Example 1 to produce a nanowire-containing light induced thermal imaging (LITI) donor sheet. The donor sheet is then placed coated side down on top of a 5 cm by 5 cm glass substrate. Laser-induced thermal transfer is then accomplished, patterning the glass substrate using a focused laser beam such as that from a CW Nd:YAG laser as described, for example, in U.S. Pat. No. 6,114,088 (Wolk). The matrix is then etched away using RIE, and the resulting pattern of nanowires is imaged using SEM.

### Example 3

### Alignment of Gold Nanorods

A dispersion of gold nanorods in water was made by first preparing gold nanoparticles seeds and then growing the seeds into gold nanoparticle rods, according to the method developed by T. K. Sau and C. J. Murphy, Langmuir, 20, (2004) 6414. A stock solution of 0.01 M HAuCl₄ (Aldrich) in ultrapure water was made. This solution was clear and yellow. A 0.1 M cetyltrimethylammonium bromide (CTAB, Aldrich) solution was prepared by dissolving 2.08 g in 60 mL ultrapure water. It was necessary to gently warm this solution to completely dissolve all the CTAB. The CTAB solution was clear and colorless. The gold nanoparticle seeds were prepared by mixing 0.250 mL of the stock HAuCl₄ solution with 7.5 mL of the stock CTAB solution and vortexing the solution for about 30 seconds. The resulting mixture was clear and orange. Then 0.600 mL of a 0.01 M sodium borohydride (NaBH₄, Aldrich) solution was added. The NaBH₄ was prepared immediately before use and chilled in an ice bath for approximately 2-3 minutes. Mixing was done by vortexing (Mini Vortexter MV 1, VWR Scientific) the solution for 30 seconds, waiting 30 seconds, and then vortexing again for 30 seconds. The mixture changed color to a reddish-brown immediately upon addition of the NaBH₄. Gold nanorods were prepared by mixing 2 mL of the stock HAuCl₄ solution with 50 mL of the stock CTAB solution. To this solution was added 5.64 mg of ascorbic acid (Aldrich). Upon addition of the ascorbic acid the solution turned clear and colorless. Finally, 0.0833 mL of gold nanoparticle seed was added followed by vortexing for 30 seconds. This solution was then left undisturbed for approximately 3 hours. Over the course of the reaction the solution turned from clear to purple in color. Because of the high concentration of CTAB the surfactant precipitated out of solution overnight. This process was hastened by storing the solution at 4° C. for 2-3 hours. The resulting solution and precipitate was washed and filtered resulting in a clear, purple solution.

To 2 g of the gold nanorod dispersion was sequentially added 60 microliters of 30% ammonium hydroxide in water, 60 microliters of 10% APG 325 in water, and 0.25 g nematic compound A to form a matrix dispersion. The matrix dispersion was stirred via magnetic stir bar for at least one hour.

The gold nanorod in the matrix dispersion was coated on silica-primed PET in the manner described in Example 1.

### Example 4

### Transfer of Aligned Gold Nanorods

Using the gold nanorod matrix dispersion described in Example 3 and the LTHCI film described in Preparatory Example 2, LITI donor sheets are prepared by coating the LTHCI film with the gold nanorod matrix dispersion according to the method described in Example 1. The gold nanorod matrix layer is transferred according to the manner described in Example 2. The matrix is then etched away using RIE, and the resulting pattern of nanowires is imaged using SEM.

### Example 5

### Alignment of Iron Oxy Hydroxide Nanorods

A suspension of iron oxy hydroxide nanorods was made by dissolving 9.9 g unoxidized crystals of FeCl₂.4H₂Oin 1 L of distilled water through which nitrogen had been bubbled for 30 minutes to remove dissolved oxygen. The solution was held in a wide-mouthed 2 L bottle. 110 ml of 1 M sodium bicarbonate was added and the nitrogen purge gas was replaced by air which was bubbled through the mixture at a flow rate of 30-40 mL/min. The mixture was continuously stirred. Oxidation was complete within 48 hours during which time the color of the suspension changed from green-blue to ochre. The pH during oxidation was self-controlled, at about 7, by the sodium bicarbonate buffer. After 48 hours the suspension was centrifuged to produce a wet cake of iron oxy hydroxide nanorods. This process was repeated until 50 g of wet cake were obtained.

About 50 g of this cake was washed by settling and decantation first with a liter of ammonium hydroxide solution prepared by adding 20 mls concentrated ammonium hydroxide to 980 ml of deionized water. The product was then washed twice with a liter of deionized water. After the final settling (over a week) the supernatant was separated by decantation and the residue was stirred to re-suspend the particles. A 6.7% (weight percent polyacrylic acid equivalence) solution of ammonium polyacrylic acid was prepared by adding concentrated ammonium hydroxide to a polyacrylic acid solution (250,000 MW, Aldrich, Milwaukee, Wis.) until the pH was 9 and diluting to 6.7% polyacrylic acid. About 4 g of this solution was added to 300 g of the washed dispersion of iron oxy hydroxide nanorods while stirring very rapidly using an IKA Works, Incorporated T18 mixer (IKA Works, Inc., Wilmington, N.C.). After this addition, the resulting dispersion was treated with ultrasonic energy using a Sonics VCX Vibracell Ultrasonic liquid processor (Sonics and Materials, Inc., Newton, Conn.) to further disperse the particles.

To 0.25 g of nematic compound A from Preparatory Example 1 is added 2 g of the above dispersion. 60 microliters of 30% ammonium hydroxide in water is added, followed by 60 microliters of 10% APG 325 in water. The iron oxy hydroxide nanorod-matrix dispersion is stirred via magnetic stir bar for at least one hour. It is then coated on a silica-primed PET in the manner described in Example 1.

### Example 6

### Transfer of Aligned Iron Oxy Hydroxide Nanorods

Using the iron oxy hydroxide nanorod matrix dispersion described in Example 5 and the LITI donor sheets described in Example 2, the LITI donor sheets are coated with the iron oxy hydroxide nanorod matrix dispersion according to the method described in Example 1. The iron oxy hydroxide nanorod matrix layer is transferred according to the manner described in Example 2. The matrix is then etched away using RIE, and the resulting pattern of nanowires is imaged using SEM.

Various modifications and alterations of this invention will become apparent to those skilled in the art without departing from the scope and principles of this invention, and it should be understood that this invention is not to be unduly limited to the illustrative embodiments set forth hereinabove.

We claim:

1. A method of making a device comprising aligned semiconducting nanoparticles and a receptor substrate, where the method comprises the steps of:
a) aligning a plurality of first semiconducting nanoparticles;
b) depositing the aligned first semiconducting nanoparticles on a first donor sheet; and
c) transferring at least a portion of the aligned first semiconducting nanoparticles to a receptor substrate by the application of laser radiation.

2. The method according to claim 1, where the semiconducting nanoparticles are inorganic semiconducting nanoparticles.

3. The method according to claim 1 wherein step a) is accomplished by alignment by capillary flow in or on a textured or microchanneled surface.

4. The method according to claim 1 wherein step a) is accomplished by alignment by templating on a self-assembled monolayer (SAM).

5. The method according to claim 1 wherein step a) is accomplished by alignment by templating on a textured polymer surface.

6. The method according to claim 1 wherein step a) is accomplished by alignment by mixing in a composition that includes nematic liquid crystals followed by shear orientation of the nematic liquid crystals.

7. The method according to claim 1 additionally comprising the steps of:
d) aligning a second plurality of second nanoparticles;
e) depositing the aligned second nanoparticles on a second donor sheet; and
f) transferring at least a portion of the aligned second nanoparticles to the same receptor substrate by the application of laser radiation.

8. The method according to claim 7, where the second nanoparticles are semiconducting nanoparticles.

9. The method according to claim 8, where the second nanoparticles differ in composition from the first semiconducting nanoparticles.

10. The method according to claim 7, where the second nanoparticles are inorganic semiconducting nanoparticles.

11. The method according to claim 10, where the second nanoparticles differ in composition from the first semiconducting nanoparticles.

12. The method according to claim 7, where the second nanoparticles are conducting nanoparticles.

13. The method according to claim 7, where the second nanoparticles are non-conducting nanoparticles.

14. The method according to claim 1 additionally comprising the steps of:
d) aligning a second plurality of second nanoparticles;
e) depositing the aligned second nanoparticles on the first donor sheet; and
f) transferring at least a portion of the aligned second nanoparticles to the same receptor substrate by the application of laser radiation.

15. The method according to claim 14, where the second nanoparticles are semiconducting nanoparticles.

16. The method according to claim 15, where the second nanoparticles differ in composition from the first semiconducting nanoparticles.

17. The method according to claim 14, where the second nanoparticles are inorganic semiconducting nanoparticles.

18. The method according to claim 17, where the second nanoparticles differ in composition from the first semiconducting nanoparticles.

19. The method according to claim 14, where the second nanoparticles are conducting nanoparticles.

20. The method according to claim 14, where the second nanoparticles are non-conducting nanoparticles.

21. A device comprising aligned semiconducting nanoparticles and a receptor substrate made according to the method of claim 1.

22. A device comprising aligned semiconducting nanoparticles and a receptor substrate made according to the method of claim 7.

23. A device comprising aligned semiconducting nanoparticles and a receptor substrate made according to the method of claim 14.
